(19) United States
(12) Patent Application Publication
(10) Pub. No.: US 2025/0212513 A1
(43) Pub. Date: Jun. 26, 2025

(54) SELECTIVE DEEP RECESS SOURCE/DRAIN STRUCTURE FOR DIRECT BACKSIDE POWER RAIL CONTACT

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/390,766

(22) Filed: Dec. 20, 2023

(51) Int. Cl. H01L 27/12

(52) U.S. Cl. CPC H10D 86/60; H10D 86/0221; H10D 86/441; H10D 86/0214

(57) ABSTRACT

A field effect transistor (FET) structure and method for making the same is disclosed. In an aspect, a FET structure comprises a gate structure, extending in a first horizontal direction and disposed between a first source/drain (S/D) epitaxial (EPI) structure and a second S/D EPI structure set apart in a second horizontal direction. The FET structure also comprises a backside inter-layer dielectric (ILD) layer disposed below the vertical metal gate structure and the first and second S/D EPI structures. The first S/D EPI structure comprises a lower portion that extends vertically below a bottom surface of the vertical metal gate structure and into the backside ILD layer, the lower portion comprising sides and a bottom surface. At least the bottom surface of the lower portion is electrically coupled to a backside contact, such as a long trench contact extending in the second horizontal direction or an extended contact island.

### BACKGROUND OF THE DISCLOSURE

### 1. Field of the Disclosure

This disclosure relates generally to semiconductor wafer process, and more specifically to gate-all-around (GAA) field effect transistors (FETs) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a field effect transistor (FET) structure includes a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and a backside inter-layer dielectric (ILD) layer disposed below the vertical metal gate structure, the first S/D EPI structure, and the second S/D EPI structure, wherein the first S/D EPI structure comprises a lower portion that extends vertically below a bottom surface of the vertical metal gate structure and into the backside ILD layer, the lower portion comprising sides and a bottom surface, and wherein at least the bottom surface of the lower portion is electrically coupled to a backside contact, such as a long trench contact extending in the second horizontal direction or an extended contact island.

In an aspect, a method of fabricating a FET structure includes providing a gate structure, extending in a first horizontal direction and disposed between a first S/D EPI structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and providing a backside ILD layer disposed below the vertical metal gate structure, the first S/D EPI structure, and the second S/D EPI structure, wherein the first S/D EPI structure comprises a lower portion that extends vertically below a bottom surface of the vertical metal gate structure and into the backside ILD layer, the lower portion comprising sides and a bottom surface, and wherein at least the bottom surface of the lower portion is electrically coupled to a backside contact, such as a long trench contact extending in the second horizontal direction or an extended contact island.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIGS. 1A and 1B are a top view and a cross-sectional view, respectively, of a conventional semiconductor structure of an integrated circuit (IC) device with backside contacts.

FIGS. 2A and 2B are a cross-sectional view and a top view, respectively, of a semiconductor structure comprising selective deep recess source/drain (S/D) epitaxial (EPI) structures for direct backside power rail contact via a long trench contact (LTC), according to aspects of the disclosure.

FIGS. 2C and 2D are a cross-sectional view and a top view, respectively, of a semiconductor structure comprising selective deep recess S/D EPI structures for direct backside power rail contact via an extended contact island (ECI), according to aspects of the disclosure.

FIGS. 3A-3I are cross-sections that illustrate steps in a process for fabricating a semiconductor structure having selective deep recess S/D EPI structures for direct backside power rail contact via an LTC, according to aspects of the disclosure.

FIGS. 4A-4F are cross-sections that illustrate steps in a process for fabricating a semiconductor structure having selective deep recess S/D EPI structures for direct backside power rail contact via ECIs, according to aspects of the disclosure.

FIG. 5 is a flowchart showing a portion of a simplified wafer process for fabricating a semiconductor structure having selective deep recess S/D EPI structures for direct backside power rail contact, according to aspects of the disclosure.

FIG. 6 is a flowchart of an example process associated with selective deep recess S/D EPI structures for direct backside power rail contact, according to aspects of the disclosure.

FIG. 7 illustrates a mobile device in accordance with some examples of the disclosure.

FIG. 8 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A field effect transistor (FET) structure having recessed source/drain (S/D) epitaxial (EPI) structures for direct backside power rail contact and methods for making the same are disclosed. In an aspect, a FET structure comprises a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels. The FET structure also comprises a backside inter-layer dielectric (ILD) layer disposed below the vertical metal gate structure, the first S/D EPI structure, and the second S/D EPI structure. The first S/D EPI structure comprises a lower portion that extends vertically below a bottom surface of the vertical metal gate structure and into the backside ILD layer, the lower portion comprising sides and a bottom surface. At least the bottom surface of the lower portion is electrically coupled to a backside contact, which may be a long trench contact (LTC) extending in the second horizontal direction or an extended contact island (ECI) that also contacts one or more sides of the lower portion of the first S/D EPI structure.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Particular aspects of the subject matter described in this disclosure can be implemented to realize one or more of the following potential advantages. Because the recessed S/D EPI structures extend below the gate structures, backside contacts are far enough away from the gate structures that there is less chance that a process error (e.g., an etch process that etched too deep, a lithography process that was not completely aligned to the wafer, etc.) will cause the backside contact to short circuit with the gate. Also, since the contact does not have to fit solely within the space between adjacent gates, a backside contact can be made with a larger surface area, which reduces contact resistance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

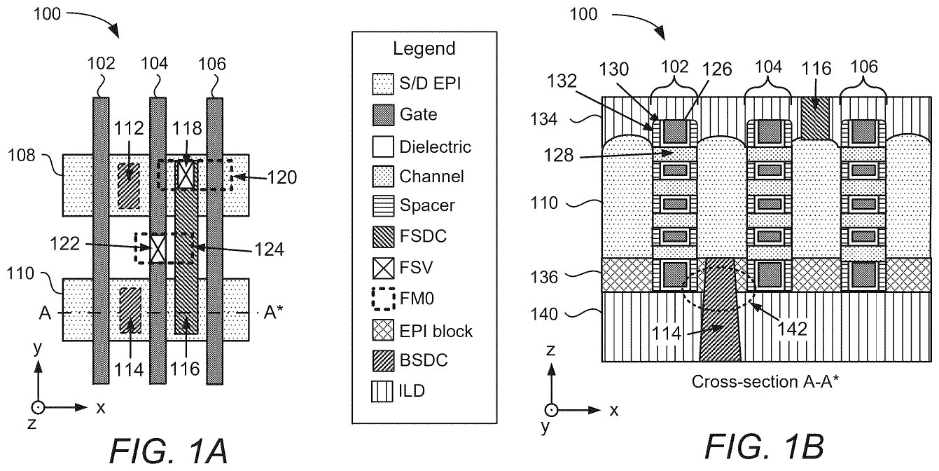

FIG. 1A is a top view of a portion of a semiconductor structure 100 of a conventional integrated circuit (IC) device with backside power. In some aspects, FIG. 1A merely shows some elements of the semiconductor structure 100 for illustration purposes, and other elements above and/or below the elements shown in FIG. 1A may be disposed but not shown in FIG. 1A. As shown in FIG. 1A, the semiconductor structure 100 includes gate stacks 102, 104, and 106 spaced along a first direction (e.g., the x direction) and having a length along a second direction (e.g., the y direction). As used herein, the term “gate stack” refers to a structure that includes a metal gate and which may also include dielectric material, an inner spacer, and other structural components. As used herein, the terms “gate” and “gate stack” are synonymous unless specifically indicated as otherwise. The semiconductor structure 100 also includes a first region 108 of epitaxial (EPI) source/drain (S/D) structures between the gate stacks and a second region 110 of EPI S/D structures between the gate stacks. The semiconductor structure 100 also includes a first backside S/D contact (BSDC) 112 and a second BSDC 114. The semiconductor structure 100 also includes a frontside S/D contact (FSDC) 116. A frontside via to diffusion (FSVD) 118 electrically connects the FSDC 116 to a first frontside metal zero (FM0) structure 120. A frontside via to gate (FSVG) 122 electrically connects the gate stack 104 to a second FM0 structure 124.

FIG. 1B is a cross-sectional view of the semiconductor structure 100 along cut-line A-A*. As can be seen in FIG. 1B, each gate cross-section includes a metal gate structure 126 through which one or more channels 128 extend, insulated from the gate metal by a dielectric 130 and insulated from the EPI structures by a spacer 132. As shown in FIG. 1B, a top inter-layer dielectric (ILD) layer 134 covers the tops of the gate stacks and EPI regions. It is through this top ILD layer 134 that the FSDC 116 extends. As shown in FIG. 1B, an EPI block or etch stop layer 136 surrounds the bottom portion of each gate, and a bottom ILD layer 140 covers the bottoms of the gate stacks and the etch stop layer 136. It is through this bottom ILD layer 140 that the second BSDC 114 extends. FIG. 1B also illustrates a disadvantage of this conventional structure-namely, that patterning steps (mask, etch, etc.) to create the second BSDC 114 must be precise enough so that the second BSDC 114 does not unintentionally make contact with the gate stacks on either side, e.g., in the area labeled 142 in FIG. 1B. To ensure that this does not happen, conventional processes constrain the side-to-side dimensions of BSDCs, which result in smaller BSDCs with higher resistance. These constraints also are a barrier to reduction of layout size, since the second BSDC 114 and the gate stacks on either side would get even closer to each other as the chip dimensions are scaled down.

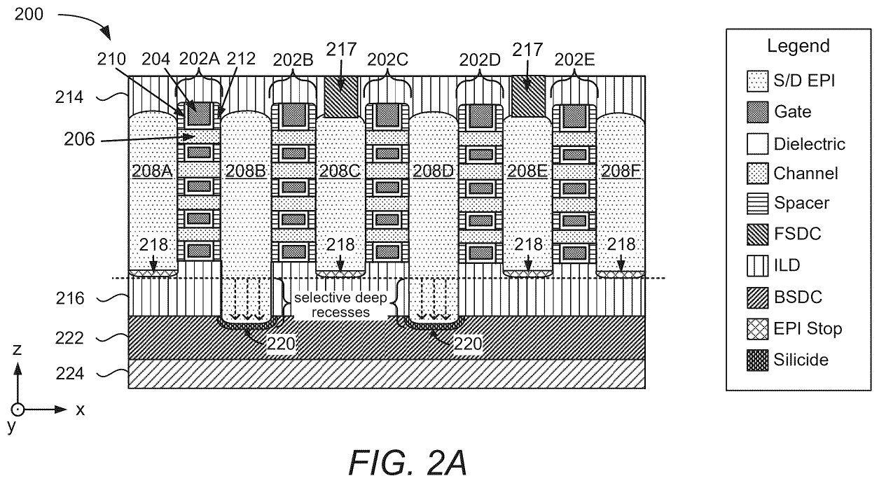

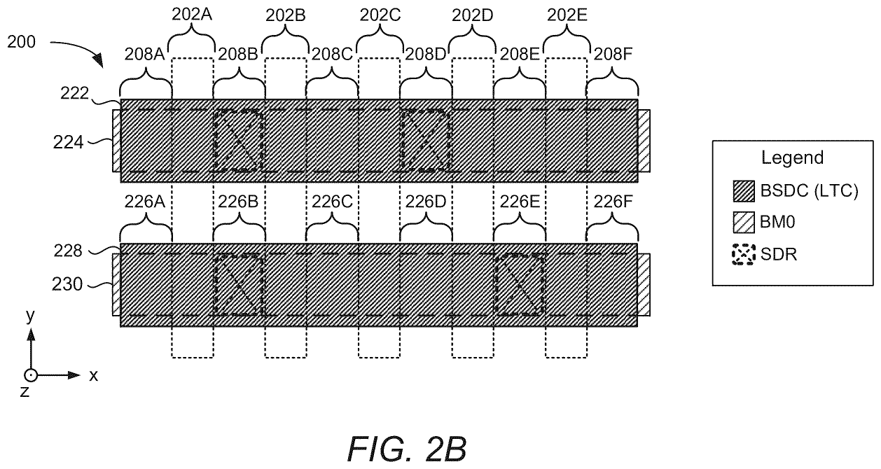

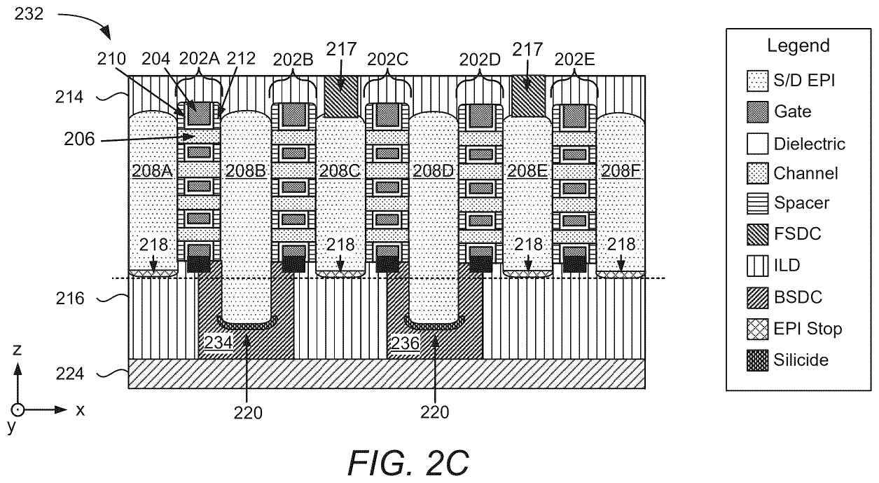

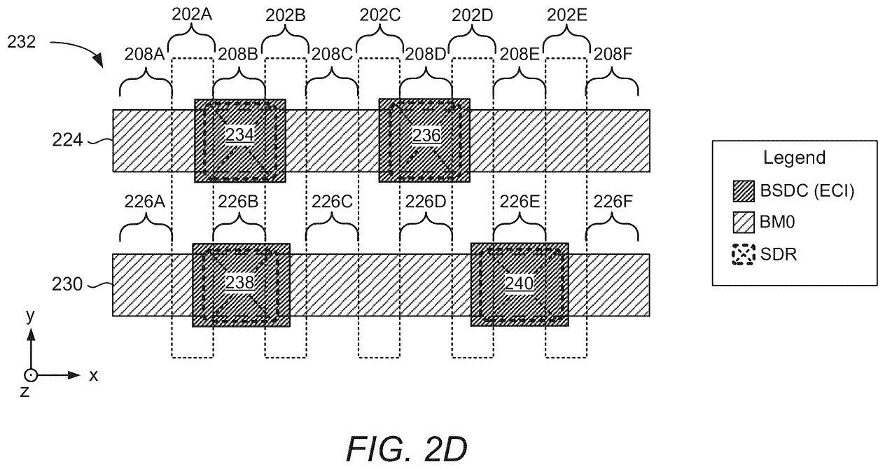

FIGS. 2A and 2B are a cross-sectional view and a top view, respectively, of a semiconductor structure 200 comprising selective deep recess S/D EPI structures for direct backside power rail contact via a long trench contact (LTC), according to aspects of the disclosure. FIG. 2A shows a cross-section of gate stacks 202A-E, which may be referred to collectively as gate stacks 202 and individually as gate stack 202A, gate stack 202B, etc. Each gate stack cross-section includes a metal gate structure 204 through which one or more channels 206 extend to connect a pair of S/D EPI structures, labeled 208A-F but which may be referred to collectively as S/D EPI structures 208 and individually as S/D EPI structure 208A, S/D EPI structure 208B, etc. Each channel 206 is insulated from the gate metal by a dielectric 210 and insulated from S/D EPI structures 208 by a spacer 212. As shown in FIG. 2A, a top ILD layer 214 covers the tops of the gate stacks and S/D EPI structures, and a bottom ILD layer 216 covers the bottoms of the gate stacks and S/D EPI structures. In the example shown in FIG. 2A, FSDCs 217 make electrical contact to 5/D EPI structures 208C and 208E.

As shown in FIG. 2A, S/D EPI structures 208A, 208C, 208E, and 208F are not recessed, and terminate at an EPI stop layer 218 relatively close to the bottoms of the gate stacks 202, while selected S/D EPI structures 208B and 208D are recessed, i.e., they extend relatively far below the bottoms of the gate stacks 202 and terminate at silicide structures 220, which provide an interface between a recessed S/D EPI structure and a BSDC structure 222. As a result, the processes to etch a hole in the substrate (later removed) on which the gate structures were fabricated for the deposition of the silicide structures 220 and for the deposition of the BSDC structure 222 does not need to be so accurate, since they are not close to the bottom of the gate stacks 202. In some aspects, the selective deep recess S/D EPI structures are those that will be connected to power or ground, e.g., to VDD or VSS. In some aspects, a backside metal-zero (BM0) structure 224 provides the backside power or ground. It will be understood that the BM0 structure 224 and BSDC structure 222 can alternatively be used for signaling rather than power or ground.

FIG. 2B, which is a top view of the semiconductor structure 200, merely shows some elements of the semiconductor structure 200 for illustration purposes, and other elements above and/or below the elements shown in FIG. 2B may be disposed but not shown in FIG. 2B. FIG. 2B shows a top view of the gate stacks 202A through 202E, and the relative locations of the S/D EPI structures 208A through 208F over the BSDC structure 222 and the BM0 structure 224. FIG. 2B also shows the relative locations of S/D EPI structures 226A through 226F over a second BSDC structure 228 and a second BM0 structure 230. In FIG. 2B, the locations of selective deep recesses are indicated by dotted outlines, i.e., under the S/D EPI structure 208B, under the S/D EPI structure 208D, under the S/D EPI structure 226B, and under the S/D EPI structure 226E. S/D EPI structures 208B and 208E are thus electrically connected to the BM0 structure 224 and S/D EPI structures 226B and 226E are thus electrically connected to the second BM0 structure 230. In the example shown in FIG. 2B, the BSDC structure 222 and the BM0 structure 224 may constitute a long trench contact, e.g., that extends along the x direction to connect all of the SDR along that line. In some aspects, the LTC can extend the full length of a cell or multiple cells. Likewise, the BSDC structure 228 and the BM0 structure 230 illustrated in FIG. 2B may constitute another long trench contact. In some aspects, BM0 structure 224 and second BM0 structure 230 are separate power rails, e.g., VDD and VSS.

FIGS. 2C and 2D are a cross-sectional view and a top view, respectively, of a semiconductor structure 232 comprising selective deep recess S/D EPI structures for direct backside power rail contact via extended contact islands (ECIs), according to aspects of the disclosure. The structural components of the semiconductor structure 232 are equivalent to their like-numbered elements in FIGS. 2A and 2B and therefore their descriptions will not be repeated here. The semiconductor structure 232 differs from the semiconductor structure 200 in that rather than a long trench contact 222 that electrically connects the recessed S/D EPI structures, as shown in FIG. 2A, ECI 234 electrically connects the S/D EPI structure 208B to the BM0 structure 224 and ECI 236 electrically connects the S/D EPI structure 208D to the BM0 structure 224. As can be seen in FIG. 2C, the ECI 234 contacts not only the bottom but also the sides of the recessed S/D EPI structure 208B, and the ECI 236 contacts not only the bottom but also the sides of the recessed S/D EPI structure 208D. This additional contact area results in a lower contact resistance between the S/D EPI structure 208B and the BM0 structure 224 and also between the S/D EPI structure 208D and the BM0 structure 224.

FIG. 2D, which is a top view of the semiconductor structure 232, merely shows some elements of the semiconductor structure 232 for illustration purposes, and other elements above and/or below the elements shown in FIG. 2D may be disposed but not shown in FIG. 2D. FIG. 2D shows a top view of the gate stacks 202A through 202E, and the relative locations of the S/D EPI structures 208A through 208F over the ECI structure 234, the ECI structure 236, and the BM0 structure 224. FIG. 2D also shows the relative locations of S/D EPI structures 226A through 226F over an ECI structure 238, an ECI structure 240, and a second BM0 structure 230. In FIG. 2D, the locations of selective deep recesses are indicated by dotted outlines, i.e., under the S/D EPI structure 208B, under the S/D EPI structure 208D, under the S/D EPI structure 226B, and under the S/D EPI structure 226E. S/D EPI structures 208B and 208E are thus electrically connected to the BM0 structure 224 and S/D EPI structures 226B and 226E are thus electrically connected to the second BM0 structure 230. In some aspects, BM0 structure 224 and second BM0 structure 230 are separate power rails, e.g., VDD and VSS.

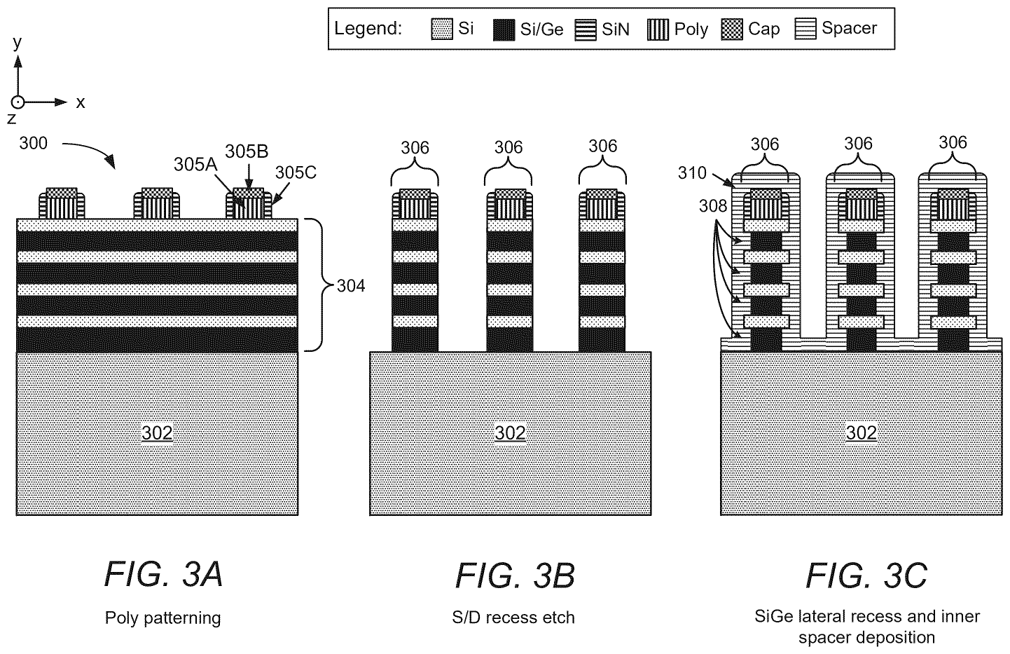

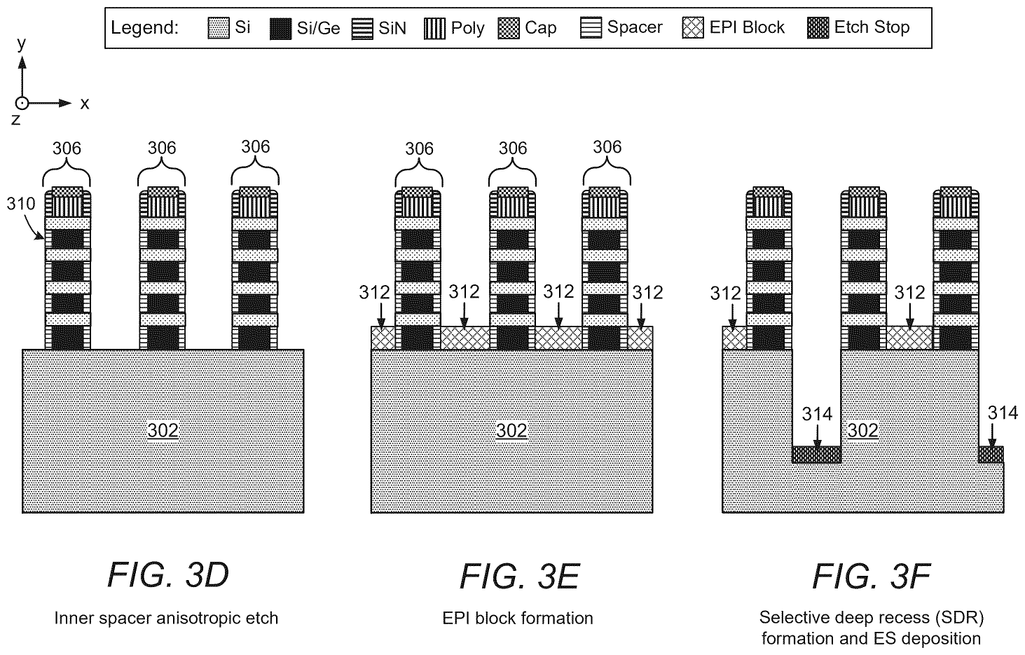

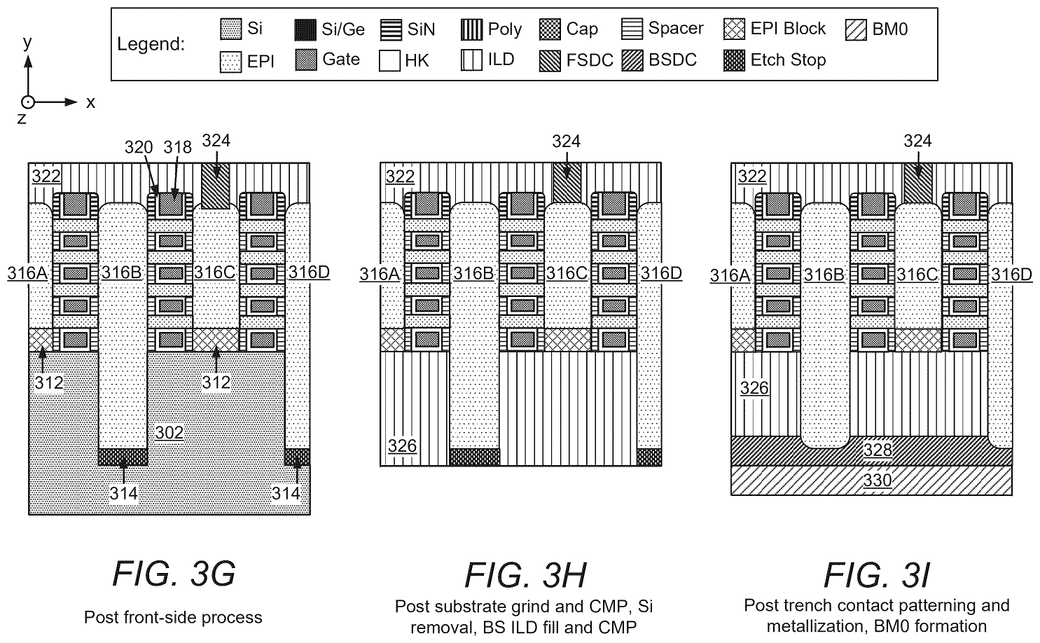

FIGS. 3A-3I are cross-sections that illustrate steps in a process for fabricating a semiconductor structure having selective deep recess S/D EPI structures for direct backside power rail contact via an LTC, according to aspects of the disclosure. As shown in FIG. 3A, the process starts with a semiconductor structure 300 comprising a silicon substrate 302 upon which have been fabricated alternating layers 304 of silicon (Si) and silicon/germanium (Si/Ge).

FIG. 3A illustrates the result after application of a polysilicon (“poly”) patterning step that is the basis for a self-aligned gate fabrication process. The poly patterning step creates structures comprising a polysilicon structure 305A topped with a cap structure 305B (e.g., a dielectric material) and flanked by sidewall spacers 305C (e.g., silicon nitride (SiN)).

FIG. 3B illustrates the result after source/drain (S/D) etching process that etches through the alternating layers 304 to form recesses in which S/D EPI will later be grown.

FIG. 3C illustrates the result after a process to create lateral recesses 308 in each gate stack 306 and to deposit a spacer material 310.

FIG. 3D illustrates the result after an anisotropic etch process that removes the spacer material 310 from the bottom of each recess and from the top of the gate stacks 306.

FIG. 3E illustrates the result after deposition of an EPI block structure 312, which may be a film, at the bottom of each recess. Materials that can be used for the EPI block structure 312 include, but are not limited to, titanium silicide (TiSi), silicon carbon nitride (SiCN), silicon carbon oxynitride (SiCON), aluminum nitride (AlN), area-selective deposition (ASD) dielectrics, SiGe EPI, and other materials that have high etch selectivity to spacer and later backside Si removal.

FIG. 3F illustrates the result after a selective recess process that creates deeper recesses where selected EPI regions will eventually be formed, such as EPI regions that will be electrically tied to VDD or VSS/GND, and deposits within those deeper recesses a silicon etch stop (ES) material 314. Materials that can be used for the ES material 314 include, but are not limited to, titanium silicide (TiSi), silicon carbon nitride (SiCN), silicon carbon oxynitride (SiCON), aluminum nitride (AlN), area-selective deposition (ASD) dielectrics, SiGe EPI, and other materials that have high etch selectivity to spacer and later backside Si removal.

FIG. 3G illustrates the result after the remainder of the front side process. In the example shown in FIG. 3G, the front side process includes an EPI formation process, resulting in S/D EPI structures 316A and 316C that extend only down to the EPI block structure 312 and S/D EPI structures 316B and 316D that extend below the bottom of the gate stacks, e.g., down to the ES material 314 at the bottom of each recess. In the example shown in FIG. 3G, the front side process also includes forming the gate metal 318 and high-K dielectric 320 structures, deposition of a top (i.e., front-side) ILD layer 322, and creation of an FSDC 324.

FIG. 3H illustrates the result after a substrate thin-down process in which the bulk of the substrate 302 is removed, followed by a process for depositing a bottom (i.e., backside) ILD 326 and performing a chemical/mechanical polishing (CMP) step. In some aspects, the substrate 302 is removed via an anisotropic etch and wet clean.

FIG. 3I illustrates the result after a process for post trench contact patterning and metallization, by which a BSDC 328 and backside metal structure 330 are created. In some aspects, the backside metal structure 330 may comprise backside-metal-zero (BM0). During these steps the ES material 314 is removed.

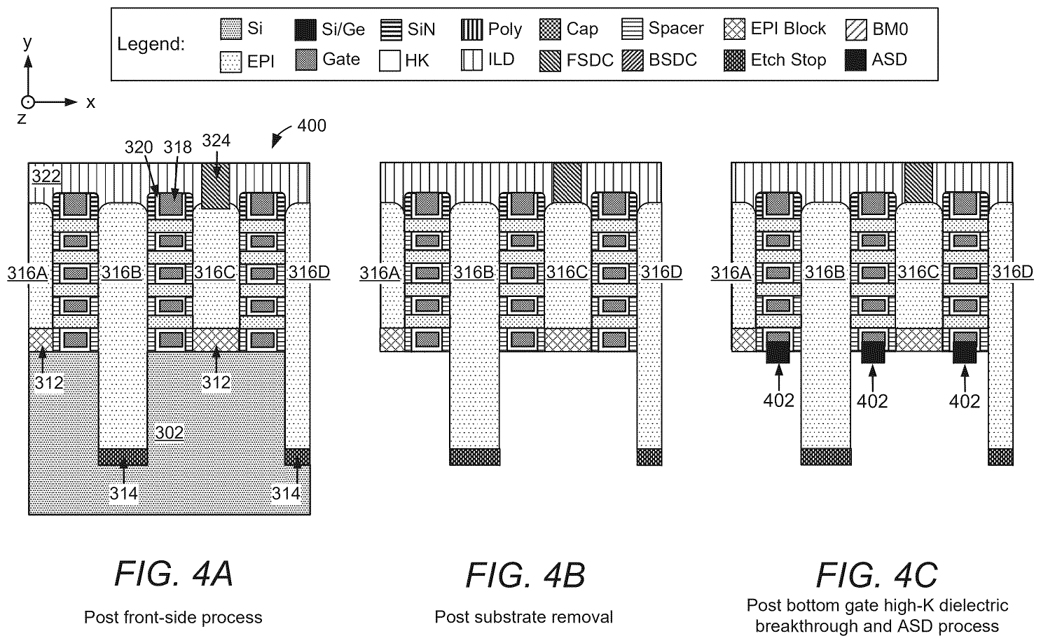

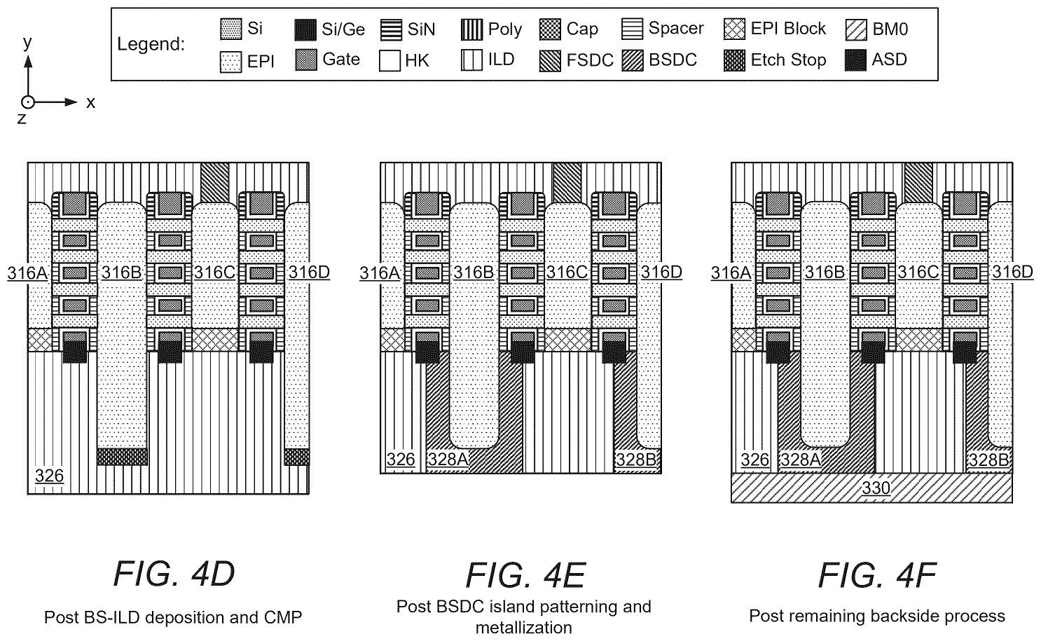

An advantage to using the selective deep recess S/D EPI structures shown in FIG. 3I, for example, is that the BSDC 328 can be the full width of the selective deep recess S/D EPI structures 316B and 316D, which increases the contact area between the BSDC and those EPI structures and reduces contact resistance. As will be shown in FIGS. 4A-4F, below, the BSDC 328 may even wrap around the sides of the selective deep recess S/D EPI structures 316B and 316D, further increasing the contact area and further reducing the contact resistance.

FIGS. 4A-4F are cross-sections that illustrate steps in a process for fabricating a semiconductor structure 400 having selective deep recess S/D EPI structures for direct backside power rail contact via ECIs, according to aspects of the disclosure. As shown in FIG. 4A, the process starts with a semiconductor structure 400 substantially the same as the semiconductor structure 300 as shown in FIG. 3G, e.g., after completion of the front side process, and descriptions of like-numbered elements will not be repeated here. As shown in FIG. 4A, the semiconductor structure 400 includes S/D EPI structures 316A and 316C that extend only down to the EPI block structure 312 and S/D EPI structures 316B and 316D that extend below the bottom of the gate stacks, e.g., down to the ES material 314 at the bottom of each recess.

FIG. 4B illustrates the result after a substrate thin-down process in which the bulk of the substrate 302 is removed, e.g., via an anisotropic etch and wet clean.

FIG. 4C illustrates the result after a process for bottom gate high-K breakthrough and area selective deposition (ASD) of a bottom cap material 402. In this example, the bottom cap material 402 is deposited only onto the exposed surface of the gate metal 318.

FIG. 4D illustrates the result after depositing a bottom ILD layer 326 and performing a chemical/mechanical polishing (CMP) step.

FIG. 4E illustrates the result after BSDC island patterning and metallization step to create the BSDCs 328. As shown in FIG. 4E, the BSDC 328A wraps around the bottom and sides of the S/D EPI structure 316B and the BSDC 328B wraps around the bottom and sides of the S/D EPI structure 316D. This provides a large contact area between a BSDC and its respective selective deep recess S/D EPI structure, which reduces the contact resistance.

FIG. 4F illustrates the result after a backside metallization process that creates the backside metal structure 330. As shown in FIG. 4F, the BSDCs 328A and 328B have a large contact surface with the backside metal structure 330, which further reduces the contact resistance.

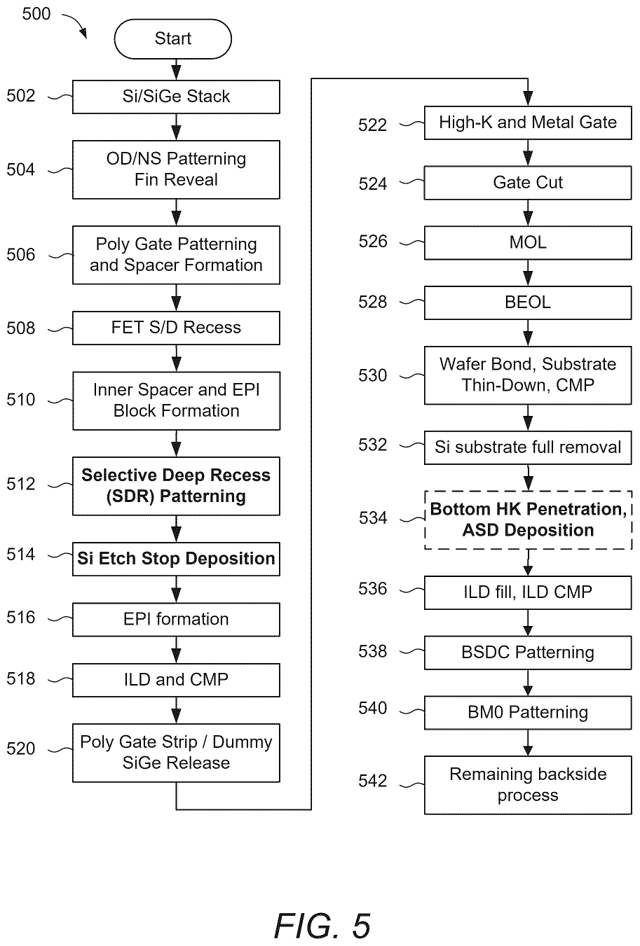

FIG. 5 is a flowchart showing a portion of a simplified wafer process for fabricating a semiconductor structure having selective deep recess S/D EPI structures for direct backside power rail contact, according to aspects of the disclosure. As shown in FIG. 5, the process 500 may include, at block 502, forming the Si/SiGe stack, e.g., to create the alternating Si and SiGe layers 304 in FIG. 3A.

The process 500 may include, at block 504, performing oxide diffusion/nanosheet patterning and fin reveal, and at block 506, polysilicon gate patterning, e.g., to produce the structures shown on the top surface of the alternating layers 304 in FIG. 3A.

The process 500 may include, at block 508, creating FET S/D recesses, e.g., by etching the alternating layers 304 to create gate stacks 306 with recesses between them, as shown in FIG. 3B.

The process 500 may include, at block 510, deposition of a spacer, e.g., such as the spacer material 310 shown in FIG. 3D, and EPI block deposition, e.g., such as the EPI block structures 312 shown in FIG. 3E.

The process 500 may include, at block 512, selective deep recess (SDR) patterning, e.g., to create the recesses shown in FIG. 3F.

The process 500 may include, at block 514, Si etch stop formation, e.g., to deposit the ES material 314 as shown in FIG. 3F.

The process 500 may include, at block 516, formation of S/D EPI structures, e.g., the S/D EPI structures 316A-D as shown in FIG. 3G.

The process 500 may include, at block 518, deposition of ILD followed by CMP, e.g., the FS-ILD layer 322 in FIG. 3G.

The process 500 may include, at block 520, performing a poly gate strip and dummy SiGe release process, at block 522, a high-K dielectric and metal gate process, and, at block 524, a gate cut process, e.g., to create the metal gates 318 and high-K dielectrics 320 as shown in FIG. 3G.

The process 500 may include, at block 526, performing a middle-of-line (MOL) process, and, at block 528, performing a back-end-of-line (BEOL) process, which completes the frontend process steps, such as shown in FIG. 3G and FIG. 4A.

The process 500 may include, at block 530, bonding the structure to a carrier wafer, flipping the structure, and performing a substrate thin-down process followed by CMP. The process 500 may include, at block 532 substrate full removal process.

The process 500 may optionally include, at optional block 534, a bottom gate high-K dielectric penetration step followed by an atomic-scale-deposition (ASD) process to create bottom gate caps, e.g., the bottom gate caps 402 in FIG. 4C. If optional block 536 is not performed, the remaining process steps are illustrated in FIG. 3I. If optional block 536 is performed, the remaining process steps are illustrated in FIGS. 4C-4F.

The process 500 may include, at block 536, an ILD fill and ILD CMP process, e.g., to result in the structure shown in FIG. 3H and in FIG. 4B.

The process 500 may include, at block 538, a BSDC patterning step, to create BSDCs, e.g., the BSDC 328 in FIG. 3I and the BSDCs 328A and 328B in FIG. 4E.

The process 500 may include, at block 540, a backside metal patterning step, e.g., to create BM0 structure 330 as shown in FIG. 3I and FIG. 4F.

The process 500 may include, at block 542, performing the remaining steps of the backside process.

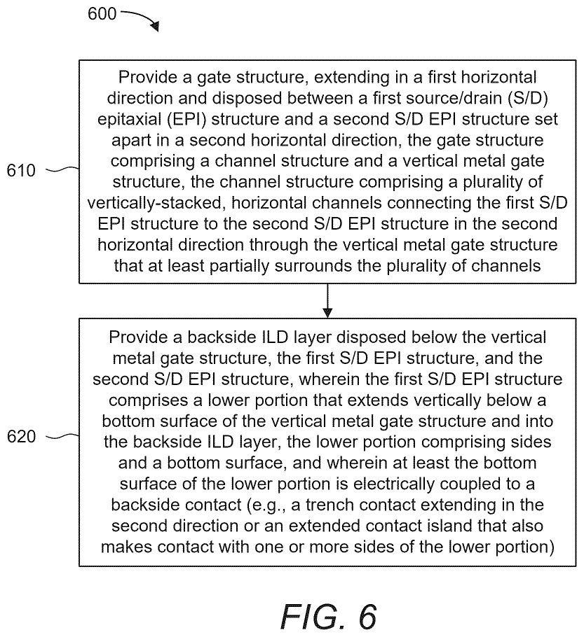

FIG. 6 is a flowchart of an example process 600 associated with selective deep recess source/drain epitaxial structure for direct backside power rail contact, according to aspects of the disclosure.

As shown in FIG. 6, process 600 may include, at block 610, providing a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels.

As further shown in FIG. 6, process 600 may include, at block 620, providing a backside ILD layer disposed below the vertical metal gate structure, the first S/D EPI structure, and the second S/D EPI structure, wherein the first S/D EPI structure comprises a lower portion that extends vertically below a bottom surface of the vertical metal gate structure and into the backside ILD layer, the lower portion comprising sides and a bottom surface, and wherein at least the bottom surface of the lower portion is electrically coupled to a trench contact extending in the second horizontal direction.

In some aspects, the trench contact comprises a power rail for providing VDD or VSS to the first S/D EPI structure.

In some aspects, the trench contact is in contact with and electrically couples with at least one of the sides of the lower portion of the first S/D EPI structure.

In some aspects, the trench contact is in direct contact with the lower portion of the first S/D EPI structure.

In some aspects, process 600 includes providing a first coupling material disposed between at least a portion of the lower portion of the first S/D EPI structure and the trench contact.

In some aspects, providing the first coupling material comprises providing silicide.

In some aspects, the trench contact comprises at least one of a backside S/D contact (BSDC) structure or a backside metal (BM) layer structure.

In some aspects, process 600 includes providing a first etch stop material disposed on at least a bottom surface of the lower portion of the second S/D EPI structure.

In some aspects, providing the first etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

In some aspects, the gate structure comprises a gate-all-around (GAA) structure.

In some aspects, process 600 includes providing a frontside inter-layer dielectric (ILD) layer disposed above the vertical metal gate structure, the first S/D EPI structure, and the second S/D EPI structure.

Process 600 may include additional implementations, such as any single implementation or any combination of implementations described below and/or in connection with one or more other processes described elsewhere herein. Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

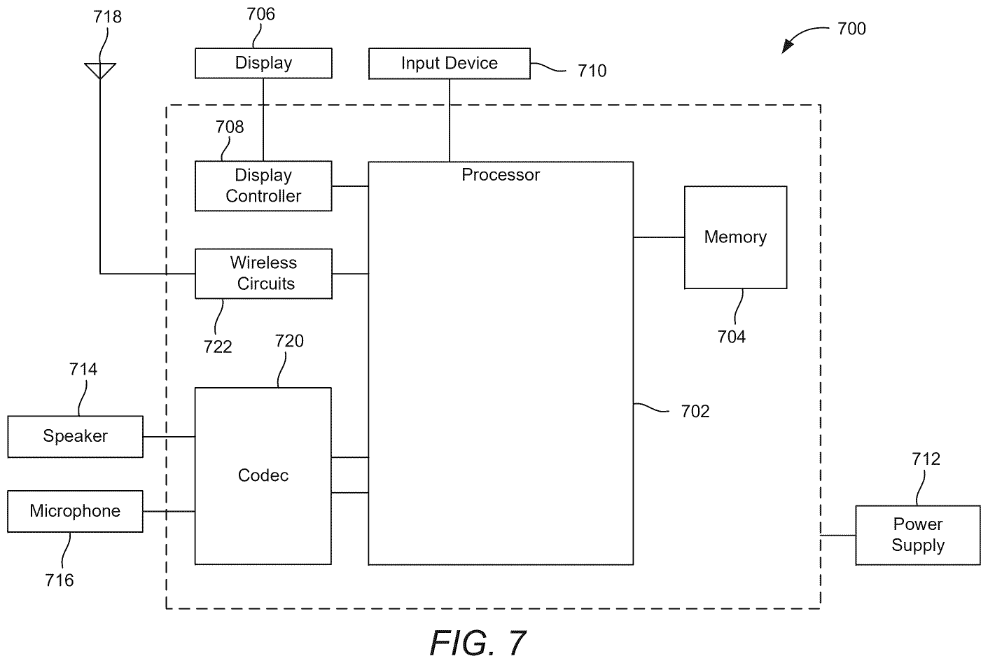

FIG. 7 illustrates a mobile device 700, according to aspects of the disclosure. In some aspects, the mobile device 700 may be implemented by including one or more IC devices manufactured based on the examples described in this disclosure.

In some aspects, mobile device 700 may be configured as a wireless communication device. As shown, mobile device 700 includes processor 702. Processor 702 may be communicatively coupled to memory 704 over a link, which may be a die-to-die or chip-to-chip link. Mobile device 700 also includes display 706 and display controller 708, with display controller 708 coupled to processor 702 and to display 706. The mobile device 700 may include input device 710 (e.g., physical, or virtual keyboard), power supply 712 (e.g., battery), speaker 714, microphone 716, and wireless antenna 718. In some aspects, the power supply 712 may directly or indirectly provide the supply voltage for operating some or all of the components of the mobile device 700.

In some aspects, FIG. 7 may include coder/decoder (CODEC) 720 (e.g., an audio and/or voice CODEC) coupled to processor 702; speaker 714 and microphone 716 coupled to CODEC 720; and wireless circuits 722 (which may include a modem, RF circuitry, filters, etc.) coupled to wireless antenna 718 and to processor 702.

In some aspects, one or more of processor 702, display controller 708, memory 704, CODEC 720, and wireless circuits 722 may include one or more IC devices including semiconductor structures manufactured according to the examples described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

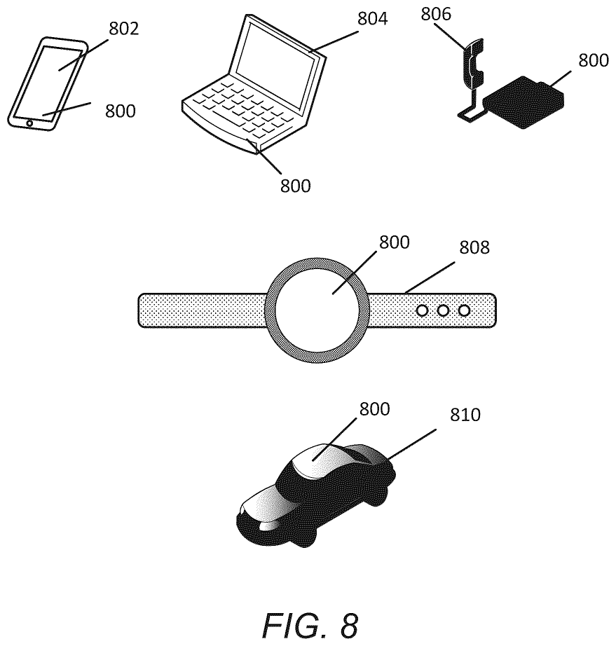

FIG. 8 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 802, a laptop computer device 804, a fixed location terminal device 806, a wearable device 808, or automotive vehicle 810 may include a semiconductor device 800 (e.g., semiconductor structure 200, semiconductor structure 300, semiconductor structure 400) as described herein. The devices 802, 804, 806 and 808 and the vehicle 810 illustrated in FIG. 8 are merely exemplary. Other apparatuses or devices may also feature the semiconductor device 800 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A field effect transistor (FET) structure, comprising: a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and a backside ILD layer disposed below the vertical metal gate structure, the first S/D EPI structure, and the second S/D EPI structure, wherein the first S/D EPI structure comprises a lower portion that extends vertically below a bottom surface of the vertical metal gate structure and into the backside ILD layer, the lower portion comprising sides and a bottom surface, and wherein at least the bottom surface of the lower portion is electrically coupled to a backside contact.

Clause 2. The FET structure of clause 1, wherein the backside contact comprises a trench contact extending in the second horizontal direction.

Clause 3. The FET structure of any of clauses 1 to 2, wherein the backside contact comprises a power rail for providing VDD or VSS to the first S/D EPI structure.

Clause 4. The FET structure of any of clauses 1 to 3, wherein the backside contact is in contact with and electrically couples with one or more of the sides of the lower portion of the first S/D EPI structure.

Clause 5. The FET structure of any of clauses 1 to 4, wherein the backside contact is in direct contact with the lower portion of the first S/D EPI structure.

Clause 6. The FET structure of any of clauses 1 to 5, further comprising a first coupling material disposed between at least a portion of the lower portion of the first S/D EPI structure and the backside contact.

Clause 7. The FET structure of clause 6, wherein the first coupling material comprises silicide.

Clause 8. The FET structure of any of clauses 1 to 7, wherein the backside contact comprises at least one of a backside S/D contact (BSDC) structure or a backside metal (BM) layer structure.

Clause 9. The FET structure of any of clauses 1 to 8, further comprising a first etch stop material disposed on at least a bottom surface of the lower portion of the second S/D EPI structure.

Clause 10. The FET structure of clause 9, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

Clause 11. The FET structure of any of clauses 1 to 10, wherein the gate structure comprises a gate-all-around (GAA) structure.

Clause 12. The FET structure of any of clauses 1 to 11, further comprising a frontside inter-layer dielectric (ILD) layer disposed above the vertical metal gate structure, the first S/D EPI structure, and the second S/D EPI structure.

Clause 13. A method of fabricating a field effect transistor (FET) structure, the method comprising: providing a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and providing a backside ILD layer disposed below the vertical metal gate structure, the first S/D EPI structure, and the second S/D EPI structure, wherein the first S/D EPI structure comprises a lower portion that extends vertically below a bottom surface of the vertical metal gate structure and into the backside ILD layer, the lower portion comprising sides and a bottom surface, and wherein at least the bottom surface of the lower portion is electrically coupled to a backside contact.

Clause 14. The method of clause 13, wherein the backside contact comprises a trench contact extending in the second horizontal direction.

Clause 15. The method of any of clauses 13 to 14, wherein the backside contact comprises a power rail for providing VDD or VSS to the first S/D EPI structure.

Clause 16. The method of any of clauses 13 to 15, wherein the backside contact is in contact with and electrically couples with one or more of the sides of the lower portion of the first S/D EPI structure.

Clause 17. The method of any of clauses 13 to 16, wherein the backside contact is in direct contact with the lower portion of the first S/D EPI structure.

Clause 18. The method of any of clauses 13 to 17, further comprising providing a first coupling material disposed between at least a portion of the lower portion of the first S/D EPI structure and the backside contact.

Clause 19. The method of clause 18, wherein providing the first coupling material comprises providing silicide.

Clause 20. The method of any of clauses 13 to 19, wherein the backside contact comprises at least one of a backside S/D contact (BSDC) structure or a backside metal (BM) layer structure.

Clause 21. The method of any of clauses 13 to 20, further comprising providing a first etch stop material disposed on at least a bottom surface of the lower portion of the second S/D EPI structure.

Clause 22. The method of clause 21, wherein providing the first etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

Clause 23. The method of any of clauses 13 to 22, wherein the gate structure comprises a gate-all-around (GAA) structure.

Clause 24. The method of any of clauses 13 to 23, further comprising providing a frontside inter-layer dielectric (ILD) layer disposed above the vertical metal gate structure, the first S/D EPI structure, and the second S/D EPI structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A field effect transistor (FET) structure, comprising:
a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and
a backside inter-layer dielectric (ILD) layer disposed below the vertical metal gate structure, the first S/D EPI structure, and the second S/D EPI structure,
wherein the first S/D EPI structure comprises a lower portion that extends vertically below a bottom surface of the vertical metal gate structure and into the backside ILD layer, the lower portion comprising sides and a bottom surface, and
wherein at least the bottom surface of the lower portion is electrically coupled to a backside contact.

2. The FET structure of claim 1, wherein the backside contact comprises a trench contact extending in the second horizontal direction.

3. The FET structure of claim 1, wherein the backside contact comprises a power rail for providing VDD or VSS to the first S/D EPI structure.

4. The FET structure of claim 1, wherein the backside contact is in contact with and electrically couples with one or more of the sides of the lower portion of the first S/D EPI structure.

5. The FET structure of claim 1, wherein the backside contact is in direct contact with the lower portion of the first S/D EPI structure.

6. The FET structure of claim 1, further comprising a first coupling material disposed between at least a portion of the lower portion of the first S/D EPI structure and the backside contact.

7. The FET structure of claim 6, wherein the first coupling material comprises silicide.

8. The FET structure of claim 1, wherein the backside contact comprises at least one of a backside S/D contact (BSDC) structure or a backside metal (BM) layer structure.

9. The FET structure of claim 1, further comprising a first etch stop material disposed on at least a bottom surface of the lower portion of the second S/D EPI structure.

10. The FET structure of claim 9, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

11. The FET structure of claim 1, wherein the gate structure comprises a gate-all-around (GAA) structure.

12. The FET structure of claim 1, further comprising a frontside inter-layer dielectric (ILD) layer disposed above the vertical metal gate structure, the first S/D EPI structure, and the second S/D EPI structure.

13. A method of fabricating a field effect transistor (FET) structure, the method comprising:
providing a gate structure, extending in a first horizontal direction and disposed between a first source/drain (S/D) epitaxial (EPI) structure and a second S/D EPI structure set apart in a second horizontal direction, the gate structure comprising a channel structure and a vertical metal gate structure, the channel structure comprising a plurality of vertically-stacked, horizontal channels connecting the first S/D EPI structure to the second S/D EPI structure in the second horizontal direction through the vertical metal gate structure that at least partially surrounds the plurality of channels; and
providing a backside inter-layer dielectric (ILD) layer disposed below the vertical metal gate structure, the first S/D EPI structure, and the second S/D EPI structure,
wherein the first S/D EPI structure comprises a lower portion that extends vertically below a bottom surface of the vertical metal gate structure and into the backside ILD layer, the lower portion comprising sides and a bottom surface, and
wherein at least the bottom surface of the lower portion is electrically coupled to a backside contact.

14. The method of claim 13, wherein the backside contact comprises a trench contact extending in the second horizontal direction.

15. The method of claim 13, wherein the backside contact comprises a power rail for providing VDD or VSS to the first S/D EPI structure.

16. The method of claim 13, wherein the backside contact is in contact with and electrically couples with one or more of the sides of the lower portion of the first S/D EPI structure.

17. The method of claim 13, wherein the backside contact is in direct contact with the lower portion of the first S/D EPI structure.

18. The method of claim 13, further comprising providing a first coupling material disposed between at least a portion of the lower portion of the first S/D EPI structure and the backside contact.

19. The method of claim 18, wherein providing the first coupling material comprises providing silicide.

20. The method of claim 13, wherein the backside contact comprises at least one of a backside S/D contact (BSDC) structure or a backside metal (BM) layer structure.

21. The method of claim 13, further comprising providing a first etch stop material disposed on at least a bottom surface of the lower portion of the second S/D EPI structure.

22. The method of claim 21, wherein providing the first etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

23. The method of claim 13, wherein the gate structure comprises a gate-all-around (GAA) structure.

24. The method of claim 13, further comprising providing a frontside inter-layer dielectric (ILD) layer disposed above the vertical metal gate structure, the first S/D EPI structure, and the second S/D EPI structure.
